(19) United States
(12) Patent Application Publication
(10) Pub. No.: US 2026/0269818 A1
(43) Pub. Date: Sep. 10, 2026

(54) POWER SEMICONDUCTOR DEVICE AND METHOD FOR FABRICATING THE SAME

(71) Applicant: HYUNDAI MOBIS CO., LTD., Seoul (KR)

(72) Inventor: Tae Yeop KIM, Yongin-si (KR)

(73) Assignee: HYUNDAI MOBIS CO., LTD., Seoul (KR)

(21) Appl. No.: 19/073,205

(22) Filed: Mar. 7, 2025

(51) Int. Cl. H03K 17/081; H03K 17/16; H10D 84/83

(52) U.S. Cl. CPC H03K 17/08104; H03K 17/162; H10D 84/83125; H03K 2217/0027

(57) ABSTRACT

A power semiconductor device, and a method therefor are provided. The power semiconductor device includes a first transistor including a first source electrode and a first drain electrode, a second transistor including a second source electrode and a second drain electrode, and a current divider electrically connected to the first source electrode and the second source electrode. The first drain electrode and the second drain electrode are electrically connected to each other.

### BACKGROUND

### Field

The present disclosure relates to a semiconductor device, and more particularly, a power semiconductor device for switching power transmission.

### Description of the Related Art

A power semiconductor device refers to a semiconductor device that operates in a high-voltage and high-current environment. Such a power semiconductor device has been used in a field, such as an inverter device, necessary for switching higher power. For example, the power semiconductor device may include an insulated gate bipolar transistor (IGBT) or a power MOSFET.

The power semiconductor device basically requires a withstand characteristic against a higher voltage. In addition, recently, the power semiconductor device has additionally required a high-speed switching operation. The semiconductor device operates, as electrons injected into a channel and a hole carrier injected into a collector flow.

A power semiconductor device may be configured with parallel components for large-current driving to perform a switching operation. Conventionally, the power semiconductor device has a voltage imbalance phenomenon occurring between components connected in parallel, due to the difference in a parasitic inductance amount in a circulating current, in switching.

When the voltage imbalance phenomenon occurs, the current crowding phenomenon may occur through one chip. Accordingly, the robustness of a semiconductor device may be degraded due to the current crowding phenomenon.

### SUMMARY

The present disclosure has been made to solve the above-mentioned problems occurring in the prior art while advantages achieved by the prior art are maintained intact.

An aspect of the present disclosure provides a power semiconductor device stably operating in parallel.

However, the above object is provided only for the illustrative purpose, and the scope and spirit of the present disclosure is not limited thereto.

The technical problems to be solved by the present disclosure are not limited to the aforementioned problems, and any other technical problems not mentioned herein will be clearly understood from the following description by those skilled in the art to which the present disclosure pertains.

In a general aspect of the present disclosure, a power semiconductor device may include a first transistor including a first source electrode and a first drain electrode, a second transistor including a second source electrode and a second drain electrode, and a current divider electrically connected to the first source electrode and the second source electrode. The first drain electrode and the second drain electrode may be electrically connected to each other.

The current divider may include a first shunt resistor electrically connected to the first source electrode, and a second shunt resistor electrically connected to the second source electrode.

The first shunt resistor may have a resistance equal to a resistance of the second shunt resistor.

The first shunt resistor may shunt a current into the first transistor, and the second shunt resistor may shunt a current into the second transistor.

The current divider may include a local oxidation of silicon (LOCOS) region including a silicon oxide, a polysilicon region positioned on the LOCOS region, an oxide region positioned on the polysilicon region, and a metal region positioned on the oxide region.

The first transistor may include a first gate electrode electrically connected to a second gate electrode included in the second transistor.

In another general aspect of the present disclosure, a power semiconductor chip may include a first main cell region including a first transistor, a second main cell region including a second transistor connected to the first transistor in parallel, a current divider including a first shunt resistor connected to a first source electrode of the first transistor and a second shunt resistor connected to a second source electrode of the second transistor, a gate terminal connected to a first gate of the first transistor and a second gate of the second transistor, and a current sense terminal configured to monitor a current of the first transistor or the second transistor.

The power semiconductor chip may include a semiconductor layer including the first main cell region and the second main cell region.

The semiconductor layer may include a silicon carbide.

In yet another general aspect of the present disclosure, a method for fabricating a power semiconductor device, may include arranging a first source electrode and a first drain electrode in a first transistor, arranging a second source electrode and a second drain electrode in a second transistor, electrically connecting a current divider to the first source electrode and the second source electrode, and electrically connecting the first drain electrode and the second drain electrode to each other.

The method may further include electrically connecting a first shunt resistor to the first source electrode in the current divider, and electrically connecting a second shunt resistor to the second source electrode in the current divider.

The first shunt resistor may have a resistance equal to a resistance of the second shunt resistor.

The method may further include configuring the first shunt resistor to shunt a current into the first transistor, and configuring the second shunt resistor to shunt a current into the second transistor.

The current divider may include a local oxidation of silicon (LOCOS) region including a silicon oxide, a polysilicon region positioned on the LOCOS region, an oxide region positioned on the polysilicon region, and a metal region positioned on the oxide region.

The method may further include electrically connecting a first gate electrode included in the first transistor to a second gate electrode included in the second transistor.

### BRIEF DESCRIPTION OF THE DRAWINGS

The above and other objects, features and advantages of the present disclosure will be more apparent from the following detailed description taken in conjunction with the accompanying drawings:

FIG. 1 is a plan view schematically illustrating a power semiconductor chip, according to an embodiment of the present disclosure;

FIG. 2 is an equivalent circuit diagram of a power semiconductor chip, according to an embodiment of the present disclosure; and

FIG. 3 is a cross-sectional view of a current divider taken along a first dashed line of FIG. 2.

### DETAILED DESCRIPTION

Hereinafter, embodiments of the present disclosure will be described with reference to accompanying drawings. However, the present disclosure may be implemented in various different forms and should not be construed as being limited to embodiments to be disclosed below. Rather, these embodiments are provided as examples so that the present disclosure will be thorough and complete and will fully convey the scope and spirit of the present disclosure to one skilled in the art. For the convenience of explanation, some components in accompanying drawings may be exaggerated or reduced in size. The same reference numerals will indicate the same components in drawings.

Unless otherwise defined, all terms used herein are to be interpreted as commonly understood by those skilled in the art. In drawings, sizes of layers and regions are exaggerated for explanation, and are thus provided to describe normal structures of the present disclosure.

The same reference numerals will indicate the same components. It will be understood that, when a component, such as a layer, an region, or a substrate, is referred to as being “on” another component, the component can be “directly” in an upper trench region of the another component, or one or more intervening components may also be present between the component and the another component. On the other hand, when one component is described as being “directly on” another component, it is understood as any intermediate component is not interposed therebetween.

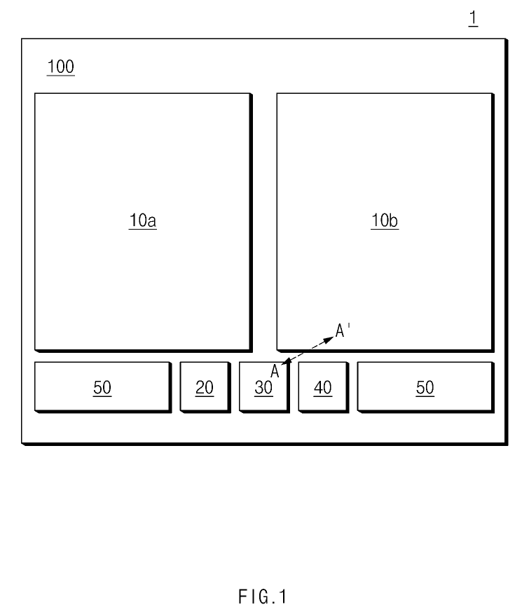

FIG. 1 is a plan view schematically illustrating a power semiconductor chip 1, according to an embodiment of the present disclosure.

Referring to FIG. 1, the power semiconductor chip 1 may include a plurality of main cell regions 10a and 10b formed in a semiconductor layer 100.

The semiconductor layer 100 may include a semiconductor substrate including a silicon carbide (SiC). As the semiconductor layer 100 includes SiC, the power semiconductor chip 1 having a higher withstanding voltage characteristic may be implemented.

Each of the main cell regions 10a and 10b may include a plurality of transistors. For example, the transistors included in each of the main cell regions 10a and 10b may be metal oxide semiconductor field effect transistors (MOSFET).

According to an embodiment, the power semiconductor chip 1 may further include a sensor region including a temperature sensor, a current sensor, and a voltage sensor, and sensor regions may be disposed in at least a partial region of the main cell regions 10a and 10b.

Each of the main cell regions 10a and 10b may include a plurality of first transistors and a plurality of second transistors. Each of the first transistors and the second transistors may be referred to as a power transistor.

For example, the first main cell region 10a may include the first transistors and the second main cell region 10b may include the second transistors.

The main cell regions 10a and 10b may have upper portions disposed with source metals to form source electrodes of the first transistors or the second transistors.

In other words, the source metals may be disposed to be overlapped with the upper portions of the main cell regions 10a and 10b, and the source electrodes including the source metals may be disposed in the main cell regions 10a and 10b.

The power semiconductor chip 1 may include a plurality of regions such as a current sense terminal 20, a gate terminal 30, a current divider 40, and a sensor terminal 50.

The current sense terminal 20 may monitor a current flowing through the transistor included in the first main cell region 10a and/or the second main cell region 10b to prevent an overcurrent from flowing through each transistor.

The gate terminal 30 may be a terminal electrically connected to gate electrodes of the transistors included in each of the main cell regions 10a and 10b.

The current divider 40 may be a region for disposing a plurality of shunt resistors connected to a side of the source electrode of each transistor. The shunt resistor may be a type of parallel resistor to measure the current.

The shunt resistor is provided, thereby improving the voltage imbalance phenomenon occurring due to the difference in the parasitic inductance between the plurality of transistors connected to each other in parallel. More specifically, the shunt resistors included in the current divider 40 may resolve the current imbalance occurring in the parallel switching of the power semiconductor device, and may improve the voltage imbalance between the transistors connected to each other in parallel.

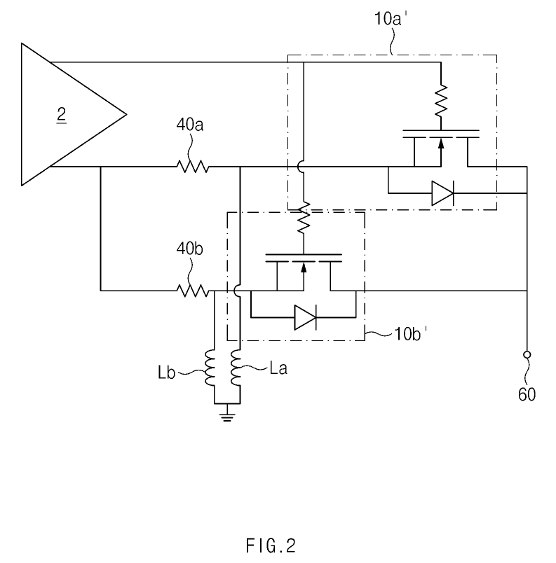

The current divider 40 may be connected to the source electrodes of mutually different transistors. More specifically, the shunt resistors included in the current divider 40 may be connected to the source electrodes of the mutually different transistors, respectively. The detailed connection structure of the shunt resistor will be described with reference to FIG. 2.

As described above, the source metals are positioned to be overlapped with the main cell regions 10a and 10b. Accordingly, the source metals positioned at the main cell regions 10a and 10b may be connected to the current divider 40 through a metal interconnection.

The shunt resistors included in the current divider 40 may be positioned at a local oxidation of silicon (LOCOS) region positioned on one surface of the semiconductor layer 100, and may include a polysilicon layer and a metal layer.

The current divider 40 may include an external terminal connected to the outside. The shunt resistors included in the current divider 40 may be connected to an external component (for example, a gate driver) through the external terminal.

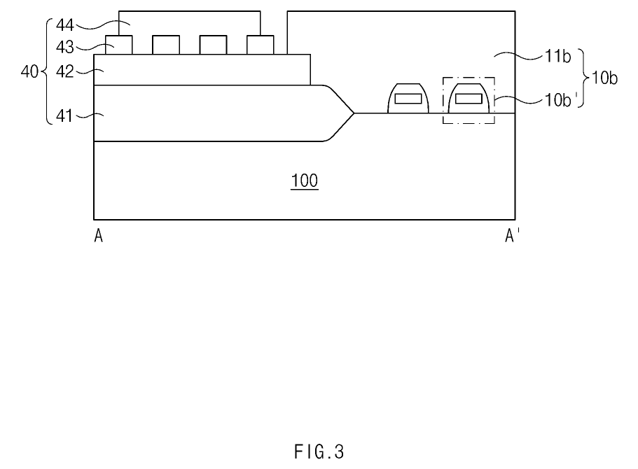

The detailed shape of the shunt resistor will be described in detail with reference to FIG. 3.

The sensor terminal 50 may further include, for example, a temperature sensor terminal connected to a temperature sensor to monitor a temperature, a Kelvin emitter terminal connected to a Kelvin emitter electrode of a power semiconductor transistor, and a Kelvin source terminal connected to a Kelvin source electrode. The types of terminals included in the sensor terminal 50 may be added or changed depending on the type of device included in the semiconductor chip 1.

Drain electrodes of power transistors may be disposed on another surface of the semiconductor layer 100. More specifically, source electrodes of the power transistors may be disposed on one surface of the semiconductor layer 100, and drain electrodes of the power transistors may be disposed on a surface facing the surface on which the source electrodes are disposed.

FIG. 2 is an equivalent circuit diagram of a power semiconductor chip, according to an embodiment of the present disclosure.

FIG. 2 illustrates an equivalent circuit diagram of the power semiconductor chip 1 including a first transistor 10a’ and a second transistor 10b’ connected to each other in parallel.

The first transistor 10a’ may be any one of power transistors positioned in the first main cell region 10a of FIG. 1, and the second transistor 10b’ may be any one of power transistors positioned in the second main cell region 10b of FIG. 1.

A first drain terminal of the first transistor 10a’ and a second drain terminal of the second transistor 10b’ may be electrically connected to each other. In other words, a first gate electrode of the first transistor 10a’ may be electrically connected to a second gate electrode of the second transistor 10b’.

More specifically, the gate electrode of the first transistor 10a′ and the gate electrode of the second transistor 10b′ may be electrically connected to the gate terminal while interposing specific resistors between the gate electrode of the first transistor 10a′ and the gate electrode of the second transistor 10b′. The specific resistor may be an internal resistor of the first transistor 10a′ or the second transistor 10b′.

The gate terminal may be electrically connected to the gate driver 2.

The gate driver 2 may operate as a power amplifier and may be a driver to provide a high-current driving signal to the gate of the first transistor 10a′ or the second transistor 10b′. The gate driver 2 may operate as an interface between the first transistor 10a′ or the second transistor 10b′, which operates as a power switch, and a control circuit.

The gate driver 2 may be provided in the form of an individual module outside the power semiconductor chip 1, or may be provided in the form of an on-chip stacked on the power the semiconductor chip 1, according to an embodiment.

In addition, the gate driver 2 may be connected to a side of the source electrode of the first transistor 10a′ or the second transistor 10b′ through the current divider 40.

The current divider 40 including the shunt resistors 40a and 40b may be interposed between the first source electrode of the first transistor 10a’ and the second source electrode of the second transistor 10b’, and the gate driver 2.

More specifically, the first shunt resistor 40a may be interposed between the first source electrode of the first transistor 10a′ and the gate driver 2. In addition, the second shunt resistor 40b may be interposed between the second source electrode of the second transistor 10b′ and the gate driver 2.

The shunt resistors 40a and 40b may be formed at the upper portion of the semiconductor layer 100 and may include a silicon oxide layer (LOCOS).

The shunt resistors 40a and 40b may include a polysilicon layer and a metal layer. The detailed shape of the shunt resistors 40a and 40b will be described in detail with reference to FIG. 3.

A first drain electrode of the first transistor 10a’ and a second drain electrode of the second transistor 10b’, which are connected to each other in parallel, may be electrically connected to one drain terminal 60.

The drain terminal 60 may be positioned on an opposite surface facing one surface, on which the source electrode is disposed, of the semiconductor layer 100, as described above.

As illustrated in FIG. 2, an inductor having an inductance, which is equal to a parasitic inductance of the first transistor 10a′ may be illustrated as a first inductor La, and an inductor having an inductance, which is equal to a parasitic inductance of the second transistor 10b′ may be illustrated as a second inductor Lb.

The parasitic inductance of the power transistor may cause the transistor to be in an overvoltage state, thereby deteriorating device characteristics and causing switching loss.

The parasitic inductance may be influenced by a wire bonding path inside the power semiconductor chip 1, an electrical property of the semiconductor layer 100 included in the power semiconductor chip 1, connection components included in the semiconductor chip 1, external components connected to the semiconductor chip 1, and a switching frequency of the semiconductor chip 1.

The voltage imbalance phenomenon may be caused between the first transistor 10a′ and the second transistor 10b′ connected to be each other in parallel, during switching of the power semiconductor chip 1 due to the difference between the parasitic inductance of the first transistor 10a′ and the parasitic inductance of the second transistor 10b′.

When the voltage imbalance occurs, a current may be crowed to any one of the first transistor 10a′ or the second transistor 10b′. When the current crowding phenomenon occurs, an excessive voltage may be applied to any one of the first transistor 10a′ or the second transistor 10b′, and the transistor may be damaged due to the overvoltage. The damage of the transistor may cause the failure of the power semiconductor chip 1.

The current divider 40 including the first shunt resistor 40a and the second shunt resistor 40b are provided to improve the current crowding phenomenon. The internal current of the power semiconductor chip 1 may be shunted through the first shunt resistor 40a and the second shunt resistor 40b, and the shunted current may be provided to the first transistor 10a′ and the second transistor 10b′.

For example, the first shunt resistor 40a and the second shunt resistor 40b may have the same resistance.

FIG. 3 is a cross-sectional view of a current divider 40 taken along a first dashed line A-A’ of FIG. 2.

FIG. 3 illustrates the semiconductor layer 100, and a portion of the second main cell region 10b, and the current divider 40 formed in the semiconductor layer 100.

As described above, the semiconductor layer 100 may include a semiconductor substrate including a silicon carbide (SiC). As the SiC substrate is provided, the semiconductor chip 1 may have a higher withstanding voltage characteristic.

The cross-section of the second main cell region 10b may be substantially the same as the cross-section of the first main cell region 10a.

The second main cell region 10b may be a region including the plurality of second transistors 10b’.

The plurality of second transistors 10b’ may be repeatedly disposed inside the second main cell region 10b.

A second source metal 11b may be provided on the second transistors 10b′. The second source metal 11b may include a metal material. The second source metal 11b may be connected to the second source electrode.

The second source metal 11b may be connected to the second shunt resistor included in the current divider 40 through the metal interconnection.

The current divider 40 may include a Local Oxidation of Silicon (LOCOS) region 41 positioned on one surface of the semiconductor layer 100. The LOCOS region 41 may be a region including a silicon oxide.

The LOCOS region 41 may be generated by a thermal oxidation method.

The LOCOS region 41 may electrically disconnect a polysilicon region 42 included in the current divider 40 from the semiconductor layer 100.

The polysilicon region 42, which is a region positioned on the LOCOS region 41, may be formed through a deposition process. The polysilicon region 42 may include conductive silicon (Si).

An oxide region 43 positioned on the polysilicon region 42 may be a region for adjusting an electrical property of the shunt resistor included in the current divider 40. For example, the conductivity of the shunt resistor positioned in the current divider 40 may be adjusted by adjusting the material included in the oxide region 43.

A metal region 44 may be formed on the oxide region 43. The metal region 44 may be a region including a metal material such as tungsten, copper, or aluminum.

The metal region 44 may be a region having an external terminal included in the current divider 40. For example, the shunt resistors included in the current divider 40 may be connected to external components through the metal region 44.

As described above, according to an embodiment of the present disclosure, there may be provided the semiconductor device improved in a voltage imbalance phenomenon occurring due to the difference in the parasitic inductance amount in the circulating current, in parallel switching.

In addition, according to an embodiment of the present disclosure, there may be provided a semiconductor device enhanced in operation stability in parallel switching, as the current divider is provided.

Such an effect is provided only for the illustrative purpose, and embodiments of the present disclosure are not limited thereto.

However, this is only an example embodiment, and it will be understood that various modifications and other equivalent embodiments are possible from this point by those skilled in the art. The technical protection scope of the present disclosure will be defined by the technical spirit of the appended claims.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A power semiconductor device comprising:
a first transistor including a first source electrode and a first drain electrode;
a second transistor including a second source electrode and a second drain electrode; and
a current divider electrically connected to the first source electrode and the second source electrode,
wherein the first drain electrode and the second drain electrode are electrically connected to each other.

2. The power semiconductor device of claim 1, wherein the current divider includes:
a first shunt resistor electrically connected to the first source electrode; and
a second shunt resistor electrically connected to the second source electrode.

3. The power semiconductor device of claim 2, wherein the first shunt resistor has a resistance equal to a resistance of the second shunt resistor.

4. The power semiconductor device of claim 2, wherein the first shunt resistor shunts a current into the first transistor, and the second shunt resistor shunts a current into the second transistor.

5. The power semiconductor device of claim 1, wherein the current divider includes:
a local oxidation of silicon (LOCOS) region including a silicon oxide;
a polysilicon region positioned on the LOCOS region;
an oxide region positioned on the polysilicon region; and
a metal region positioned on the oxide region.

6. The power semiconductor device of claim 1, wherein the first transistor includes a first gate electrode electrically connected to a second gate electrode included in the second transistor.

7. A power semiconductor chip comprising:
a first main cell region including a first transistor;
a second main cell region including a second transistor connected to the first transistor in parallel;
a current divider including a first shunt resistor connected to a first source electrode of the first transistor and a second shunt resistor connected to a second source electrode of the second transistor;
a gate terminal connected to a first gate of the first transistor and a second gate of the second transistor; and
a current sense terminal configured to monitor a current of the first transistor or the second transistor.

8. The power semiconductor chip of claim 7, further comprising:
a semiconductor layer including the first main cell region and the second main cell region.

9. The power semiconductor chip of claim 8, wherein the semiconductor layer includes a silicon carbide material.

10. A method for fabricating a power semiconductor device, the method comprising:
arranging a first source electrode and a first drain electrode in a first transistor;
arranging a second source electrode and a second drain electrode in a second transistor;
electrically connecting a current divider to the first source electrode and the second source electrode; and
electrically connecting the first drain electrode and the second drain electrode to each other.

11. The method of claim 10, further comprising:
electrically connecting a first shunt resistor to the first source electrode in the current divider; and
electrically connecting a second shunt resistor to the second source electrode in the current divider.

12. The method of claim 11, wherein the first shunt resistor has a resistance equal to a resistance of the second shunt resistor.

13. The method of claim 11, further comprising:
configuring the first shunt resistor to shunt a current into the first transistor; and
configuring the second shunt resistor to shunt a current into the second transistor.

14. The method of claim 10, wherein the current divider comprises:
a local oxidation of silicon (LOCOS) region including a silicon oxide;
a polysilicon region positioned on the LOCOS region;
an oxide region positioned on the polysilicon region; and
a metal region positioned on the oxide region.

15. The method of claim 10, further comprising:
electrically connecting a first gate electrode included in the first transistor to a second gate electrode included in the second transistor.
